(19) United States
(12) Patent Application Publication
(10) Pub. No.: US 2025/0294843 A1
(43) Pub. Date: Sep. 18, 2025

(54) METHOD FOR REGULATING METAL-SEMICONDUCTOR CONTACT BY INTERLAYER ELECTRIC DIPOLES

(71) Applicants: Tsinghua University, Beijing (CN); HON HAI PRECISION INDUSTRY CO., LTD., New Taipei (TW)

(72) Inventors: ZUO-PING ZHOU, Beijing (CN); YANG WEI, Beijing (CN); XI CHEN, Beijing (CN); SHOU-SHAN FAN, Beijing (CN)

(21) Appl. No.: 19/072,030

(22) Filed: Mar. 6, 2025

(30) Foreign Application Priority Data
Mar. 15, 2024 (CN) 202410302945.2

(51) Int. Cl. H10D 62/80; H10D 64/64

(52) U.S. Cl. CPC H10D 62/883; H10D 64/64

(57) ABSTRACT

A method for regulating metal-semiconductor contact by interlayer electric dipoles is provided. The method comprises providing a two-dimensional van der Waals superlattice metal material and a two-dimensional semiconductor; testing a surface dipole direction of the two-dimensional van der Waals superlattice metal material; switching a termination surface of the two-dimensional van der Waals superlattice metal material by mechanical peeling as needed; and contacting the required two-dimensional van der Waals superlattice metal material with the two-dimensional semiconductor, and regulating the metal-semiconductor contact by the electric dipole between the two-dimensional van der Waals superlattice metal material and the two-dimensional semiconductor.

### CROSS-REFERENCE TO RELATED APPLICATIONS

This application claims all benefits accruing under 35 U.S.C. § 119 from China Patent Application No. 202410302945.2, filed on Mar. 15, 2024, in the China National Intellectual Property Administration, the contents of which are hereby incorporated by reference.

### FIELD

The invention relates to a method for regulating metal-semiconductor contact by using interlayer electric dipoles.

### BACKGROUND

Two-dimensional materials with high carrier mobility, such as graphene, black phosphorus, and transition metal dichalcogenides (TMDCs), are considered as candidates for next-generation semiconductor devices due to their layered structures and smooth surfaces without dangling bonds. However, the metal electrodes on two-dimensional semiconductors have a great influence on the performance of two-dimensional electronic devices. The tuning of the interface Schottky barrier is an important issue because it is severely affected by the Fermi level pinning effect (FLPE) at the contact, not only on traditional semiconductor materials but also on two-dimensional semiconductors. Important research progress has shown that van der Waals (vdW) contacts can effectively solve this problem by suppressing metal induced gap states (MIGS) and thus reducing FLPE. In addition to transferring metal films or two-dimensional metal materials to two-dimensional semiconductors, vdW contacts can also be obtained by growing two-dimensional metal TMDCs on two-dimensional semiconductors with high quality. These techniques make it possible to design suitable Schottky barrier heights and have broad application prospects in low-dimensional devices. Two-dimensional transistors with low contact resistance can be realized by VS₂/MoSe₂ van der Waals contacts or WTe₂/WSe₂ van der Waals contacts. In addition, Au/WSe₂ and Pt/MoS₂ van der Waals contacts can be used to obtain Schottky junctions with rectifying properties. The great potential of van der Waals contacts makes it of great significance and value to explore new methods to design van der Waals contact interfaces.

Two-dimensional van der Waals superlattice (vdWSL) will bring more opportunities for van der Waals contact engineering. Two-dimensional vdWSL is formed by alternating stacking of sulfide blocking layers and TMDC layers in the c-axis direction. Compared with traditional TMDCs, the interlayer coupling between TMDC layers is weakened in vdWSL, and additional interlayer interactions between TMDC layers and blocking layers are introduced. For example, the PbSe blocking layer in (PbSe)_{1.14}NbSe₂ leads to exotic two-dimensional electronic structure and anisotropic superconductivity. The BiSe blocking layer in (BiSe)_{1.09}TaSe₂ reduces the thermal conductivity, resulting in a very low Seebeck coefficient and charge density wave phenomenon. More unique physical properties can be verified in vdWSL due to the charge transfer between TMDC layers and blocking layers. In [(EuS)_{1.5}]_{1.15}NbS₂, the valence change of Eu ions caused by charge transfer between the NbS₂ layer and the EuS barrier layer leads to a wonderful magnetic structure. In addition, charge transfer between the barrier layer and the TMDC layer is extensive in vdWSLs, resulting in efficient carrier doping into the TMDC layer, with a doping concentration comparable to that induced by ionic liquids.

However, an important but neglected degree of freedom in vdWSLs is the interlayer dipole caused by charge transfer.

### BRIEF DESCRIPTION OF THE DRAWINGS

Implementations of the present technology will now be described, by way of example only, with reference to the attached FIG.s, wherein:

FIG. 1 is a graph showing the resistivity variation with temperature of the two-dimensional metal vdWSL Ba₆Ta₁₁S₂₈ provided in an embodiment of the present invention, and the inset shows an optical image of the Ba₆Ta₁₁S₂₈ crystal.

FIG. 2 is the electronic potential energies of the two-dimensional metal vdWSL Ba₆Ta₁₁S₂₈ provided in an embodiment of the present invention, wherein a work function of BTS with TaS₂ layer on the surface and BTS with Ba₃TaS₅ layer on the surface is 5.88 eV.

FIG. 3 is the electronic potential energies of the two-dimensional metal vdWSL Ba₆Ta₁₁S₂₈ provided in an embodiment of the present invention, wherein a work function of BTS with TaS₂ layer on the surface and BTS with Ba₃TaS₅ layer on the surface is 2.19 eV.

FIG. 4 is a KPFM image of two pieces of Ba₆Ta₁₁S₂₈ set on a SiO₂/Si wafer provided in an embodiment of the present invention.

FIG. 5 is a schematic diagram of the Ba₆Ta₁₁S₂₈/WSe₂ Schottky junction device and external circuit provided in an embodiment of the present invention.

FIG. 6 is a transfer curve of bipolar WSe₂ provided in an embodiment of the present invention, with a bias voltage of 0.4 V applied to device 1 and a bias voltage of 3.0 V applied to device 2.

FIG. 7 is an optical image of device 1 according to one embodiment.

FIG. 8 is an I-V contour plot of device 1 according to one embodiment.

FIG. 9 is an output curve of device 1 at VG=−40V and +40V according to one embodiment.

FIG. 10 is an optical image of device 2 according to one embodiment.

FIG. 11 is an I-V contour plot of device 2 according to one embodiment.

FIG. 12 is an output curve of device 2 at VG=−40V and +40V according to one embodiment.

FIG. 13 is a schematic diagram of scanning photocurrent microscopy (SPCM) measurement of a two-dimensional transistor device.

FIG. 14 is an optical image of a SPCM region of 10×10 μm for device 1.

FIG. 15 is an optical image of a SPCM region of 10×10 μm for device 2.

FIG. 16 is SPCM images of device 1 and device 2.

FIG. 17 is band alignments of device 1 and device 2 before and after contact, and a band diagram explaining the SPCM measurement results.

FIG. 18 shows the crystal structure of the two-dimensional van der Waals superlattice metal material (LaSe)_{1.14}(NbSe₂)₂.

FIG. 19 shows the crystal structure of the two-dimensional van der Waals superlattice metal material (PbSe)_{1.14}NbSe₂.

FIG. 20 shows the crystal structure of the two-dimensional van der Waals superlattice metal material [(EuS)_{1.5}]_{1.15}NbS₂.

FIG. 21 shows the crystal structure of the two-dimensional van der Waals superlattice metal material Ba₆Nb₁₁S₂₈.

### DETAILED DESCRIPTION

The disclosure is illustrated by way of example and not by way of limitation in the FIG.s of the accompanying drawings in which like references indicate similar elements. It should be noted that references to “another,” “an,” or “one” embodiment in this disclosure are not necessarily to the same embodiment, and such references mean “at least one.”

It will be appreciated that for simplicity and clarity of illustration, where appropriate, reference numerals have been repeated among the different FIG.S to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts have been exaggerated to illustrate details and features of the present disclosure better.

Several definitions that apply throughout this disclosure will now be presented.

The term “substantially” is defined to be essentially conforming to the particular dimension, shape, or other feature which is described, such that the component need not be exactly or strictly conforming to such a feature. The term “comprise,” when utilized, means “comprise, but not necessarily limited to”; it specifically indicates open-ended inclusion or membership in the so-described combination, group, series, and the like. The term of “first”, “second” and the like, are only used for description purposes, and should not be understood as indicating or implying their relative importance or implying the number of indicated technical features. Thus, the features defined as “first”, “second” and the like expressly or implicitly comprise at least one of the features. The term of “multiple times” means at least two times, such as two times, three times, etc., unless otherwise expressly and specifically defined.

An embodiment of the present invention provides a method for regulating metal-semiconductor contact by using interlayer electric dipoles. The method for regulating metal-semiconductor contact by using interlayer electric dipoles comprises the following steps:
S1: providing a two-dimensional van der Waals superlattice metal material and a two-dimensional semiconductor;
S2: testing the surface dipole direction of the two-dimensional van der Waals superlattice metal material;
S3: switching the termination surface of the two-dimensional van der Waals superlattice metal material by mechanical peeling as needed; and
S4: contacting the required two-dimensional van der Waals superlattice metal material with the two-dimensional semiconductor, and use the electric dipole between the two-dimensional van der Waals superlattice metal material and the two-dimensional semiconductor to regulate the metal-semiconductor contact.

Specifically, this embodiment provides a method for regulating the contact between atwo-dimensional metal vdWSLBa₆Ta₁₁S₂₈ (BTS) and a two-dimensional semiconductor WSe₂ by using an interlayer electric dipole.

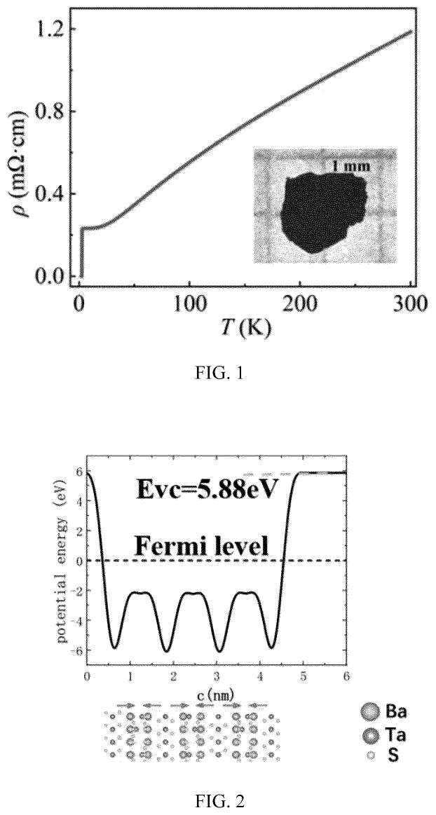

In step 1, a two-dimensional metal vdWSL Ba₆Ta₁₁S₂₈ (BTS) crystal and a two-dimensional semiconductor WSe₂ is provided. WSe₂ is a typical two-dimensional bipolar semiconductor with high electron and hole mobility. BTS crystals are synthesized by molten salt method. As shown in the inset of FIG. 1, BTS crystals are silvery white, about 1.5 mm in diameter and less than 0.1 mm in thickness. The lattice structure is analyzed by TEM observation with high spatial resolution along the a-axis of the crystal. BTS crystals are composed of a superlattice structure of Ba₃TaS₅ layers and TaS₂ layers, in which Ba₃TaS₅ is a barrier layer and TaS₂ is a TMDC layer. The thickness of the Ba₃TaS₅ layer is 0.86 nm, and the lattice constant in the c-axis direction is 2.414 nm. Transmission electron microscopy observations also show that the BTS crystals are of high quality. The resistivity-temperature curve is measured by the four-point probe method using a comprehensive physical property measurement system (QD ppms-14t). As shown in FIG. 1, the BTS crystal exhibits typical metallic properties, with a resistivity of 1.2 mΩ·cm at 300 K. Below 2.6 K, the BTS crystal enters a superconducting state.

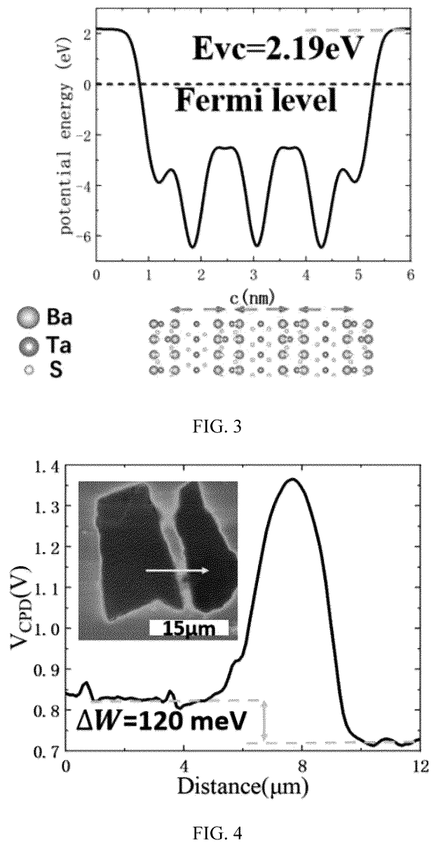

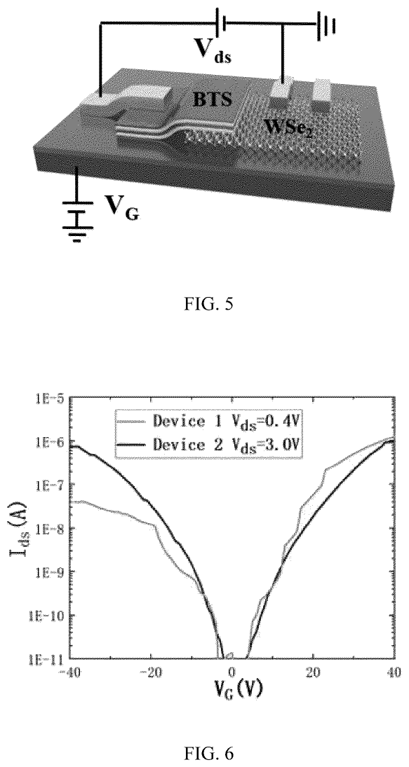

In step 2, the function of the electron potential energy inside and on the surface of BTS in the c-axis direction is shown in FIGS. 2 and 3, wherein the Fermi level is set to 0 eV, and the potential energy of the vacuum region far away from the BTS surface represents the vacuum energy level (Evc) of the corresponding surface. Inside the BTS, the electron potential energy of the Ba₃TaS₅ layer is higher than that of the TaS₂ layer, as shown in FIGS. 2 and 3, so more electrons are accumulated in the TaS₂ layer. However, since the BTS is electrically neutral, the Ba₃TaS₅ layer is positively charged, while the TaS₂ layer is negatively charged. Therefore, an interlayer dipole is formed, and its direction points from the TaS₂ layer to the Ba₃TaS₅ layer. It can be seen that the superlattice structure induces charge transfer between adjacent Ba₃TaS₅ layers and TaS₂ layers and generates interlayer dipoles. The crystal has two possible mechanically exfoliated surfaces, namely the Ba₃TaS₅₅ termination surface and the TaS₂ termination surface. The surface dipole direction of the BTS with a TaS₂ layer on the surface is inward, that is, toward the direction of the BTS, and is negative. The surface dipole direction of the BTS with a Ba₃TaS₅ layer on the surface is outward, that is, toward the direction outside the BTS, and is positive. This embodiment uses first-principles calculations to reveal the charge transfer and interlayer dipoles in the BTS.

The surface dipole of the BTS will have an important influence on its work function. The work function of a material is determined by the material itself and its surface dipole, that is, WF=F-ep/ε0, where WF is the work function of the material, F is the work function of the material without a surface dipole, p is the surface dipole density, and ε0 is the vacuum dielectric constant. The surface dipole direction of the BTS with a TaS₂ layer on the surface is inward, which is negative, and the surface dipole direction of the BTS with a Ba₃TaS₅ layer on the surface is outward, which is positive. Therefore, the work function of the BTS with a TaS₂ layer on the surface is higher than the work function of the BTS with a Ba₃TaS₅ layer on the surface. This conclusion can also be understood through a simplified physical image. The negative surface dipole introduces an additional interlayer electric field on the surface, which is directed outward. The dipole-induced surface electric field makes it more difficult for electrons to escape from the surface into the vacuum. Therefore, the negative surface dipole induces a higher work function. As for the positive surface dipole, the opposite is true. This principle can be further verified by the first-principles calculations shown in FIGS. 2 and 3. The work function can be calculated from the difference between the vacuum energy level and the Fermi level. The work functions of BTS with TaS₂ layer on the surface and BTS with Ba₃TaS₅ layer on the surface are 5.88 eV and 2.19 eV, respectively. The work function of TaS2 crystal is 4.8 eV, which is smaller than that of BTS with TaS₂ layer on the surface, indicating that the surface dipole does have an important effect on the work function of the material.

In addition, the potential difference between the two types of surfaces of BTS was qualitatively studied using Kelvin probe microscopy (KPFM). FIG. 4 shows the KPFM images of two BTS films with opposite surface dipoles, which were transferred to SiO₂/Si substrates by polydimethylsiloxane (PDMS). The green and blue parts in the KPFM image represent two BTS films. The potential inside each film is almost the same, indicating that a relatively uniform surface is obtained. The difference in the two colors indicates the surface potential difference between the two, which can be further verified by VCPD along the white arrow in FIG. 4. Since both thin films are peeled from the same BTS crystal, the different surface potentials are caused by opposite surface dipoles. According to the measurement principle of KPFM, the BTS on the left (green) has a larger work function than the BTS on the right (blue), so it can be inferred that the BTS surface on the left is a TaS₂ layer (surface dipole facing inward, negative), while the right is a Ba₃TaS₅ layer (surface dipole facing outward, negative).

Therefore, the first-principles calculation can be used to determine the direction of the BTS surface dipole, or the Kelvin probe microscope (KPFM) can be used to observe the direction of the BTS surface dipole.

In step S3, as mentioned above, the direction of the BTS surface dipole can be determined by first-principles calculations and Kelvin probe microscopy (KPFM). If it is not the desired surface, the surface of the two-dimensional van der Waals superlattice metal material can be peeled off by mechanical peeling to expose a new surface, and then the direction of the BTS surface dipole can be determined by the above method until it is the desired surface.

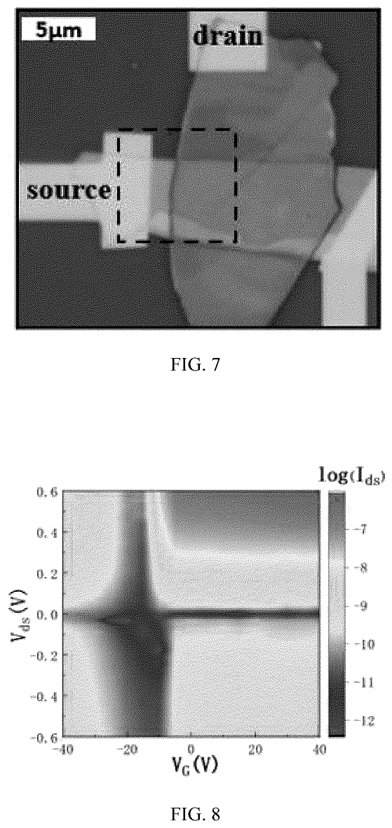

In Step S4, based on the above calculations and tests, a two-dimensional transistor with a BTS contact electrode is designed and manufactured to show the effects caused by having two surface dipoles. WSe₂ is used as a two-dimensional semiconductor channel because it is a typical two-dimensional bipolar semiconductor with high electron and hole mobility. According to the calculation of the band structure of BTS and WSe₂, it is known that BTS with a TaS₂ layer on the surface or BTS with a Ba₃TaS₅ layer on the surface can be used to contact WSe₂ to inject holes or electrons into the channel. The device is prepared by stacking a two-dimensional WSe₂ film and a BTS film on a SiO₂/Si wafer in sequence, and the BTS film is placed on the surface of the WSe₂ film by a dry transfer method. FIG. 7 shows a two-dimensional transistor formed by a BTS film with a TaS₂ layer on the surface and a WSe₂ film, referred to as device 1. Specifically, a WSe₂ film and a BTS film with a TaS₂ layer on the surface are stacked on the SiO₂/Si wafer in sequence, the TaS₂ layer of the BTS film is in contact with the WSe₂ film, an electrode is provided on the surface of the BTS film, and an electrode is provided on the WSe₂ film. FIG. 10 shows a two-dimensional transistor formed by a BTS film with a TBa₃TaS₅ layer on the surface and a WSe₂ film, referred to as device 2. Specifically, a WSe₂ film and a BTS film with a TBa₃TaS₅ layer on the surface are stacked on the SiO₂/Si wafer in sequence, the TBa₃TaS₅ layer of the BTS film is in contact with the WSe₂ film, an electrode is provided on the surface of the BTS film, and an electrode is provided on the WSe₂ film. In device 1 and device 2, the electrodes set on WSe₂ and BTS are used as source and drain, respectively. In order to test the intrinsic properties of the WSe₂ film, another electrode can be set on the WSe₂ film, and the two electrodes on the WSe₂ film can be used to test its intrinsic properties. The silicon in the SiO₂/Si film is p-doped silicon and is used as a global back gate (VG). The three electrodes are composed of 5 nm Ti and 50 nm Au (Ti/Au). It can be understood that the three electrodes can also be made of other electrode materials without limitation.

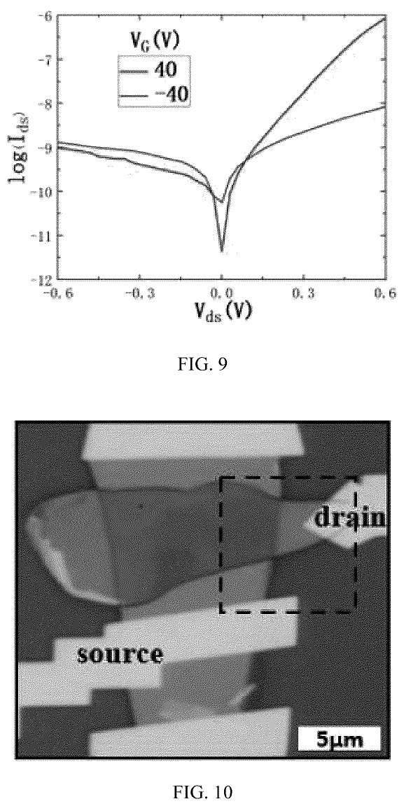

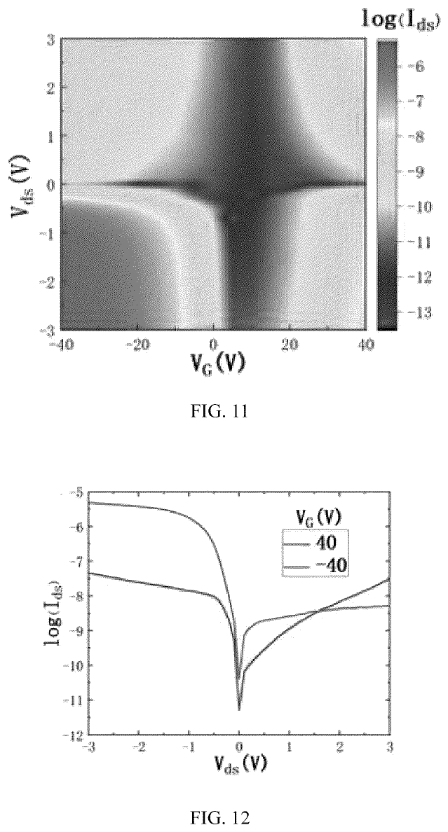

The Schottky contact between the WSe₂ film and the BTS film was studied by electrical transport measurements. As shown in FIG. 6, the WSe₂ channel in both devices exhibits typical bipolar and near-neutral semiconductor characteristics because the WSe₂ channel can be turned on by a positive or negative gate voltage (VG). Among them, when VG>0 V, the carriers of the WSe₂ channel are negative electrons, and when VG<0 V, the carriers of the WSe₂ channel are holes. The I-V contour plots in FIGS. 8 and 12 show the electrical transport performance of the two devices, where the current (Ids) varies with the bias voltage (Vds) and VG on a logarithmic scale. The two devices have significant differences in electrical performance. The more obvious characteristics are the red color on the first quadrant (+VG, +Vds) of device 1 and the third quadrant (−VG, −Vds) of device 2. Since the WSe₂ channel exhibits typical bipolar behavior, the carrier type can be modulated by VG. Therefore, device 1 and device 2 exhibit rectification characteristics for electrons and holes, respectively. When device 1 is at VG=+40 V and device 2 is at VG=−40 V, its rectification ratio can reach 103, as shown in FIGS. 9 and 11. It can be seen that two different types of Schottky diodes with rectification modes have been realized by contacting the BTS film with the WSe₂ film, which have high rectification ratios for electrons and holes, respectively.

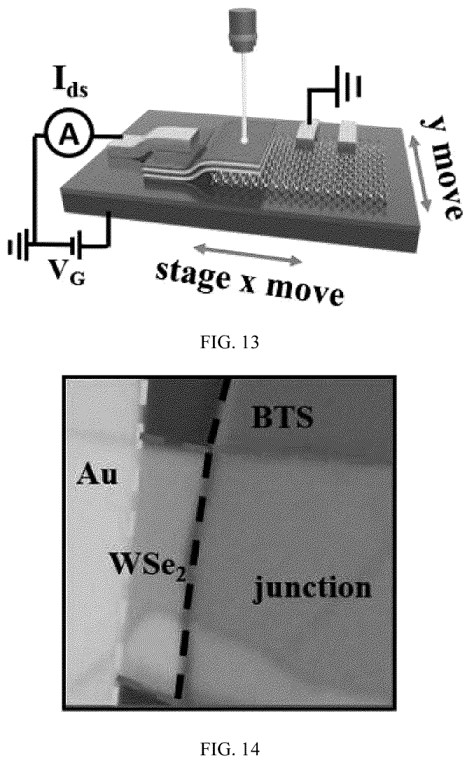

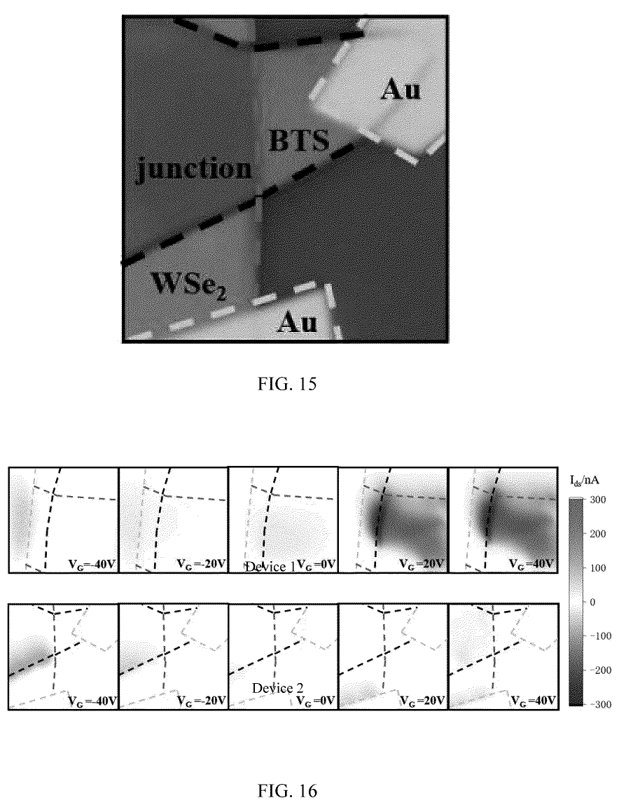

Scanning photocurrent microscopy (SPCM) measurements further revealed the direction of the built-in electric field at the BTS/WSe₂ contact interface. As shown in FIG. 13, the SPCM image was drawn by scanning the junction with a focused laser beam and recording the photocurrent and position simultaneously. The area scanned by SPCM is outlined by the dotted lines in FIGS. 7 and 10, where the size is 10×10 μm. FIGS. 15 and 16 are enlarged views of the dotted boxes in FIGS. 7 and 10, respectively, and the dotted lines represent the boundaries of the two-dimensional material and the electrode. The boundaries of BTS, Ti/Au electrodes, and WSe₂ are represented by black, yellow, and blue dotted lines, respectively. FIG. 16 shows SPCM images of device 1 and device 2 under the same color scale, where the dotted lines are the same as in FIGS. 14 and 15. Where VG is −40 V˜+40 V, Vds=0 V. The photocurrent of the device can be modulated by VG. In device 1, VG>0 V and VG<0 V in device 2 generate photocurrent, indicating that a strong Schottky junction is produced at this time. Another obvious phenomenon is that the two devices can generate opposite photocurrents, as shown in the blue and red areas in the SPCM images. The opposite photocurrents can further reveal the two types of Schottky junctions, which are established by the opposite surface dipoles of the two BTS surfaces in contact with WSe₂. Since the photocurrent is in the same direction as the built-in electric field, more information about the built-in electric field and the charge transfer at the vdW contact interface can be inferred from these SPCM images. For device 1, the negative photocurrent at VG>0 V indicates the current from WSe₂ to the BTS electrode. Therefore, the direction of the built-in electric field is from WSe₂ to BTS, which is due to the transfer of interface electrons from WSe₂ to BTS when the two materials are in contact. For device 2, when VG<0 V, the photocurrent, built-in electric field direction and interface electron transfer direction are from the BTS electrode to WSe₂, which is opposite to that of device 1.

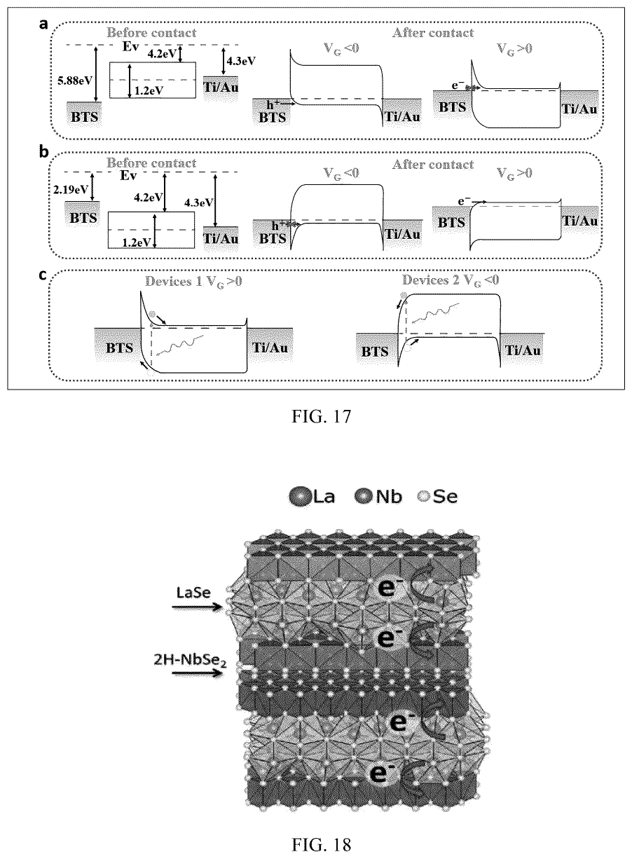

Interface charge transfer combined with work function calculation shows that before contact, the Fermi level of BTS in device 1 is located near the top of the valence band of WSe₂, while that in device 2 is located near the bottom of the conduction band of WSe₂, as shown in the left images of FIG. 17. Therefore, the BTS films of device 1 and device 2 are TaS₂ termination surface and Ba₃TaS₅ termination surface, respectively. The mechanism of photocurrent generation can be explained by the band arrangement shown in figure c of FIG. 17, where the left and right images correspond to device 1 and device 2, respectively. In device 1, the band bending of N-type WSe₂ caused by the Schottky junction at the vdW contact separates the photogenerated carriers, causing electrons to move toward WSe₂ and holes to move toward BTS. Therefore, a negative photocurrent (Ids<0) can be observed in the right image of FIG. 16. For device 2, the band bending is just the opposite. Electrons move toward the BTS and holes move toward the WSe₂, forming a positive photocurrent (Ids>0).

The electrical transport behavior can also be understood by the energy band arrangement. For the BTS terminated by TaS₂ (negative dipole, device 1), the high work function makes the BTS electrode behave as a p-type contact electrode material, as shown in figure a of FIG. 17. At VG>0, the WSe2 channel is n-type and the Schottky barrier between WSe₂ and BTS is high (as shown in the right image of in figure a of FIG. 17). Electrons from the BTS are blocked by the Schottky barrier. Therefore, the electron transfer between BTS and WSe₂ shows a clear rectification phenomenon. When VG<0 (the middle image in figure a of FIG. 17) sets the WSe₂ channel to p-type, the Schottky barrier becomes weak. Therefore, the flow of holes has no direction selectivity. For the BTS terminated by Ba₃TaS₅, the low work function makes the BTS electrode behave as an n-type contact electrode material. As shown in figure b of FIG. 17, the Schottky barrier is strong at VG<0 and weak at VG>0. As shown in FIGS. 12 and 13, holes in BTS are blocked by Schottky barriers, while electrons are not, resulting in significant rectification behavior at VG<0. In general, the difference in work functions of the two different termination surfaces leads to the rectification mode and SPCM measurement results.

Therefore, the surface dipole makes the 2D metallic vdWSL material a new type of regulated Schottky contact material. First-principles calculations of BTS show that the interlayer dipole is caused by the charge transfer between the TaS₂ layer and the Ba₃TaS₅ layer. When the BTS crystal is mechanically exfoliated, two types of termination surfaces can be formed due to its superlattice structure: TaS₂ layer or Ba₃TaS₅ layer. Therefore, the BTS with TaS₂ and Ba₃TaS₅ termination surfaces have negative and positive surface dipoles, which can be explained by KPFM measurements. The switchable surface dipole has a strong modulation effect on the work function of the BTS, which is 5.88 eV and 2.19 eV for BTS terminated with TaS₂ and Ba₃TaS₅, respectively. Due to the surface dipole and van der Waals contact, vdWSL materials can be used to construct different 2D Schottky diodes, which are obtained in BTS/WSe₂ vdW heterostructures.

Effective verification. Due to the two surfaces of BTS and bipolar WSe₂, all BTS/WSe₂ devices can be divided into two categories according to the rectification direction or contact type. The BTS electrode with TaS₂/Ba₃TaS₅ as the termination surface can form a P/N type contact with WSe₂ due to their respective hole or electron injection capabilities. The SPCM image reveals the corresponding opposite photocurrents and opposite interface built-in electric fields at the Schottky contact interface, further confirming that the device presents an N/P type Schottky junction at +/−VG.

It can be understood that the vdWSL material of the present invention is not limited to Ba₆Ta11S₂₈ (BTS) and the two-dimensional semiconductor is not limited to WSe₂. Other two-dimensional metal vdWSLs can be (LaSe)_{1.14}(NbSe₂)₂, (PbSe)_{1.14}NbSe₂, [(EuS)_{1.5}]_{1.15}NbS₂, Ba₆Nb₁₁S₂₈, etc. Other two-dimensional semiconductors can be WS₂, MoSe₂, InSe, MoS₂, MoTe₂, etc.

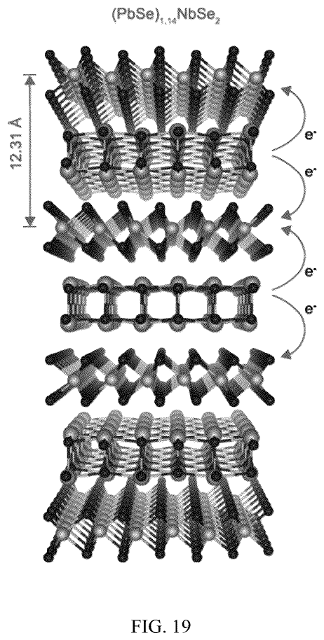

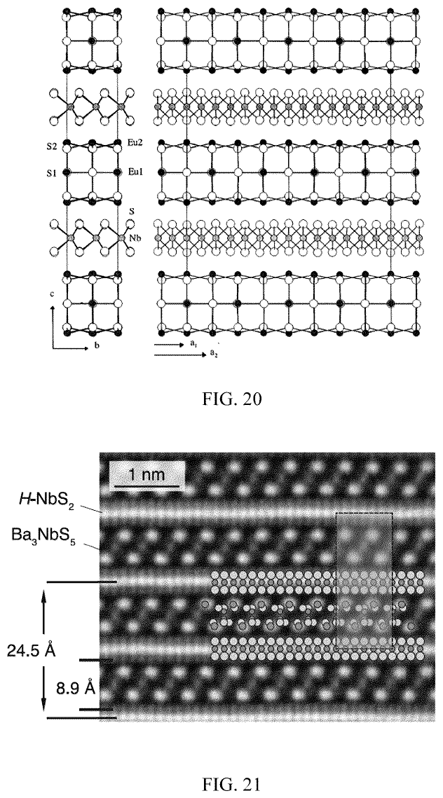

Please refer to FIGS. 18 to 21. In the (LaSe)_{1.14}(NbSe₂)₂ crystal structure, the LaSe layer and the NbSe₂ layer are alternately stacked in the c-axis direction, the LaSe layer is a barrier layer, and the NbSe₂ layer is a transition metal disulfide layer. The arrow indicates the direction of interlayer electron transfer, thereby forming an interlayer dipole, and a surface dipole can be generated after mechanical peeling. Similarly, in (PbSe)_{1.14}NbSe₂, the PbSe layer and the NbSe₂ layer are alternately stacked in the c-axis direction, the PbSe layer is a barrier layer, and the NbSe₂ layer is a transition metal disulfide layer. The arrow indicates the direction of interlayer electron transfer, thereby forming an interlayer dipole, and a surface dipole can be generated after mechanical peeling. In the [(EuS)_{1.5}]_{1.15}NbS₂ crystal structure, EuS layers and NbS₂ layers are alternately stacked in the c-axis direction, the EuS layer is a barrier layer, and the NbS₂ layer is a transition metal disulfide layer. In the Ba₆Nb₁₁S₂₈ crystal structure, Ba₃NbS₅ layers and NbS₂ layers are alternately stacked in the c-axis direction, the Ba₃NbS₅ layer is a barrier layer, and the NbS₂ layer is a transition metal disulfide layer.

It can be seen that the two-dimensional vdWSL with surface dipoles will become a new method for designing metal-semiconductor contacts. Due to the switchable characteristics of the surface dipole, vdWSL can achieve a wider range of work functions, making it a universal electrical contact material for constructing high-quality two-dimensional Schottky barriers. Compared with traditional electrode materials, vdWSL electrodes can obtain two types of contacts using one vdWSL crystal, and even inject electrons or holes into the same semiconductor channel by changing its surface dipole. In addition to flexible design, suppression of metal-induced surface states and FLPE, vdWSL electrodes also bring new degrees of freedom. The surface dipole can be used to regulate the Schottky contact interface and increase the diversity of van der Waals contacts. Thus, more functional low-dimensional devices can be developed.

The method of regulating metal-semiconductor contact with interlayer electric dipoles provided by the present invention can switch the termination surface of the two-dimensional van der Waals superlattice metal material by mechanical peeling. The surface dipoles of different termination surfaces are inward or outward, and the switchable surface dipole has a strong modulation effect on the work function of the two-dimensional van der Waals superlattice metal material. The two-dimensional van der Waals superlattice metal material and the two-dimensional semiconductor form a Schottky junction, which can produce two types of rectification effects. These behaviors can be attributed to the use of two-dimensional van der Waals superlattice metal material electrodes. When the surface of the two-dimensional van der Waals superlattice metal material is a sulfide barrier layer or a transition metal disulfide layer, two different surface dipoles can be obtained. Due to the existence of these two surface dipoles, the two-dimensional van der Waals superlattice metal material exhibits different work functions, thereby forming an N or P type contact with the two-dimensional semiconductor, realizing two types of rectification behaviors. In addition, the two Schottky junctions were studied using scanning photocurrent microscopy (SPCM), revealing the built-in electric field at the contact interface. The opposite photocurrent further verified that the two-dimensional van der Waals superlattice metal material formed an N or P type contact with the two-dimensional semiconductor channel. This shows that the surface dipoles of the two-dimensional van der Waals superlattice metal material can be used to modulate the interfacial Schottky barrier at the metal-semiconductor contact. This progress also opens up a new method for designing and regulating the van der Waals contact interface using interlayer dipoles and the two-dimensional van der Waals superlattice metal material family, giving device design more degrees of freedom and having practical application value in nanoelectronics and nanophotonics.

It is to be understood that the above-described embodiments are intended to illustrate rather than limit the present disclosure. Variations can be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

Depending on the embodiment, certain of the steps of a method described can be removed, others can be added, and the sequence of steps can be altered. The description and the claims drawn to a method may comprise some indication in reference to certain steps. However, the indication used is only to be viewed for identification purposes and not as a suggestion as to an order for the steps.

What is claimed is:

1. A method to regulate metal-semiconductor contact by interlayer electric dipoles, comprising:
providing a two-dimensional van der Waals superlattice metal material and a two-dimensional semiconductor;
testing a surface dipole direction of the two-dimensional van der Waals superlattice metal material;
changing/manipulating a termination surface of the two-dimensional van der Waals superlattice metal material by mechanical peeling according to a preset condition; and
creating a metal-semiconductor contact between the two-dimensional van der Waals superlattice metal material with the two-dimensional semiconductor, and regulating the metal-semiconductor contact according to an electric dipole between the two-dimensional van der Waals superlattice metal material and the two-dimensional semiconductor.

2. The method of claim 1, wherein the two-dimensional van der Waals superlattice metal material is provided by alternately stacking sulfide barrier layers and transition metal disulfide compound layers in a c-axis direction.

3. The method of claim 2, wherein the termination surface of the two-dimensional van der Waals superlattice metal material is manipulated such that the termination surface of the two-dimensional van der Waals superlattice metal material is a sulfide barrier layer or a transition metal disulfide compound layer.

4. The method of claim 1, wherein testing the surface dipole direction of the two-dimensional van der Waals superlattice metal material comprises: measuring a work function of a surface of the two-dimensional van der Waals superlattice metal material with a Kelvin probe microscope, and then inferring the surface dipole direction of the two-dimensional van der Waals superlattice metal material according to the work function.

5. The method of claim 1, wherein a direction of the dipole on the termination surface of the two-dimensional van der Waals superlattice metal material is regulated by switching the termination surface of the two-dimensional van der Waals superlattice metal material through mechanical peeling.

6. The method of claim 1, wherein a material of the two-dimensional van der Waals superlattice metal is Ba₆Ta₁₁S₂₈, (LaSe)_{1.14}(NbSe₂)₂, (PbSe)_{1.14}NbSe₂, [(EuS)_{1.5}]_{1.15}NbS₂ or Ba₆Nb₁₁S₂₈.

7. The method of claim 1, wherein a material of the two-dimensional semiconductor is WSe₂, WS₂, MoSe₂, InSe, MoS₂ or MoTe₂.

8. The method of claim 6, wherein when the material of the two-dimensional van der Waals superlattice metal is Ba₆Ta₁₁S₂₈ and the termination surface of the two-dimensional van der Waals superlattice is a TaS₂ layer, the surface dipole direction of the two-dimensional van der Waals superlattice metal Ba₆Ta₁₁S₂₈ is inward.

9. The method of claim 6, wherein when the termination surface of the two-dimensional van der Waals superlattice Ba₆Ta₁₁S₂₈ is a Ba₃Ta₅ layer, a surface dipole direction of the Ba₆Ta₁₁S₂₈ is outward.
